(19) United States
(12) Patent Application Publication
(10) Pub. No.: US 2013/0099359 A1
(43) Pub. Date: Apr. 25, 2013

(54) SEMICONDUCTOR PACKAGE AND STACKED SEMICONDUCTOR PACKAGE

(71) Applicant: Sung Min KIM, Seoul (KR)

(72) Inventor: Sung Min KIM, Seoul (KR)

(73) Assignee: SK hynix Inc., Icheon-si (KR)

(21) Appl. No.: 13/565,396

(22) Filed: Aug. 2, 2012

(30) Foreign Application Priority Data
Oct. 21, 2011 (KR) 10-2011-0108307

(51) Int. Cl. H01L 23/488; H01L 25/07

(52) U.S. Cl. 257/621; 257/737; 257/E23.023; 257/E25.018

(57) ABSTRACT

A semiconductor package includes a semiconductor chip having a plurality of bonding pads, dielectric members formed over the semiconductor chip in such a way as to expose portions of respective bonding pads and having a trapezoidal sectional shape, and bumps formed to cover the exposed portions of the respective bonding pads and portions of the dielectric members and having a step-like sectional shape.

### CROSS-REFERENCE TO RELATED APPLICATIONS

The present application claims priority under 35 U.S.C 119(a) to Korean patent application number 10-2011-0108307 filed on Oct. 21, 2011, which is incorporated by reference herein in its entirety.

### BACKGROUND OF THE INVENTION

1. Field of Invention

The present invention relates to a semiconductor package and a stacked semiconductor package, and more particularly, to a semiconductor package and a stacked semiconductor package which can prevent bumps from being short-circuited.

2. Description of the Related Art

These days, as electronic/electric products trend toward high performance, electronic appliance size and weight has decreased. Therefore, in order to meet requirements toward light weight, slim, compact and miniaturized products, thin formation and high dense mounting of a semiconductor packages is important.

Currently, in desktop PCs, notebooks, mobile phones, etc., as the capacity of chips such as a RAM (random access memory) and flash memory chips increases, the trend toward miniaturization of a semiconductor package becomes prominent. Thus, a semiconductor package used as an essential part has been researched and developed to have a miniature size, and various technologies for mounting an increased number of semiconductor packages on a substrate with a limited size has been suggested and researched.

Owing to this fact, a technology capable of minimizing the size and thickness of a semiconductor package while using a chip with the same memory capacity has been suggested. As an example, the semiconductor package manufactured using this technology is referred to as a flip chip package.

Such a flip chip package provides advantages in that, a bonding process capable of high density packaging is used and the positions of bonding pads in the internal circuit of a semiconductor chip is determined as needed, thus circuit design may be simplified, and resistance by circuit wiring decreased, and power consumption may be reduced. Moreover, in the flip chip package, since the path of an electrical signal is shortened, the operating speed of a semiconductor package may be improved. Thus, excellent electrical characteristics may be acquired, and since the back side of the semiconductor chip is exposed to an outside, excellent thermal characteristics may be acquired.

Typically in the flip chip package, a substrate and a semiconductor chip are electrically connected with each other using solder pastes or bumps.

Recently, in order to overcome problems caused in a stack package using metal wires and to prevent electrical characteristics of the stack package from deteriorating and enable miniaturization, research for a stack package using through electrodes has been actively conducted.

In the stack package using through electrodes, when stacking individual semiconductor chips, an adhesive is interposed between the through electrodes of the semiconductor chips which are brought into contact with each other, and a liquid phase filler is filled in the space between the semiconductor chips excluding the adhesive through an underfill process, by which the semiconductor chips are electrically and physically connected with each other.

Because an electrical connection is formed using through electrodes, electrical degradation is prevented, the operating speed of the semiconductor chips is improved, and it is possible to actively accommodate the trend toward miniaturization.

Typically, electrical connections between stacked semiconductor chips are formed using a connection member which is interposed between the projecting portion of through electrode where the projecting portion projects out of the lower surface of an upper semiconductor chip and the upper pad of a lower semiconductor chip to be brought into contact with each other. The connection member may be solders, for example.

However, in the course of electrically connecting the stacked semiconductor chips, a problem frequently occurs because the upper semiconductor chip and the lower semiconductor chip are likely to be electrically short-circuited.

In detail, semiconductor chips with through electrodes including upper pads are electrically connected by the medium of the connection member. That is to say, the connection member interposed between the projecting portion of the through electrode of the upper semiconductor chip and the upper pad of the lower semiconductor chip is melted using a reflow process, by which the upper and lower semiconductor chips are electrically connected with each other.

In this regard, the connection members melted through the reflow process is likely to leak into the lower surface of the lower semiconductor chip along with the projecting portions of the through electrode of the upper semiconductor chip and be attached to the lower surface of the lower semiconductor chip. As a partial thickness of the lower semiconductor chip is removed from the lower surface of the lower semiconductor chip through a back grinding process, the silicon substance constituting the lower semiconductor chip is exposed to an outside as it is. Because a semiconductor chip made of silicon is a semiconductor capable of allowing fine current to pass therethrough, a problem is frequently caused in that the upper semiconductor chip and the lower semiconductor chip are likely to be electrically short-circuited. Such short-circuiting may lead to the misoperation of the semiconductor chip and abrupt decrease of manufacturing yield.

### BRIEF SUMMARY OF THE INVENTION

Embodiments of the present invention are directed to a semiconductor package and a stacked semiconductor package which can prevent the manufacturing yield from decreasing due to short-circuits of bumps not having a fine pitch.

In one embodiment of the present invention, a semiconductor package includes: a semiconductor chip having a plurality of bonding pads, dielectric members formed over the semiconductor chip in such a way as to expose portions of respective bonding pads and having a trapezoidal sectional shape; and bumps formed to cover the exposed portions of the respective bonding pads and portions of the dielectric members and having a step-like sectional shape.

Each bump may include: a first flat portion formed over the exposed portion of the bonding pad; an inclined portion obliquely extending from an end of the first flat portion and formed over a side surface of the dielectric member; and a second flat portion extending from an end of the inclined portion to a middle of an upper surface of the dielectric member.

The bumps may include: a seed metal layer covering the exposed portions of the bonding pads and portions of the dielectric members; and metal plating layers formed over the seed metal layer.

The metal plating layers may include a first metal layer which has a first melting point and a second metal layer which has a second melting point lower than the first melting point.

In another embodiment of the present invention, a semiconductor package includes: a semiconductor chip having a first surface on which a plurality of bonding pads are formed and a second surface which faces away from the first surface, and formed with through electrodes which pass through the first surface and the second surface and are connected with respective bonding pads; dielectric members formed over the first surface in such a way as to expose portions of the respective bonding pads and, formed over the first and second surface such that the through electrodes are not covered and where the dielectric members have a trapezoidal sectional shape; and bumps formed over exposed portions of the first surface and the second surface of the semiconductor chip and portions of the dielectric members, and having a step-like sectional shape.

Each bump may include: a first flat portion formed over the exposed portion of the bonding pad; an inclined portion obliquely extending from an end of the first flat portion and formed over a side surface of the dielectric member; and a second flat portion extending from an end of the inclined portion to a middle of an upper surface of the dielectric member.

The bumps may include: a seed metal layer covering the exposed portions of the bonding pads and portions of the dielectric members; and metal plating layers formed over the seed metal layer.

The metal plating layers may include a first metal layer which has a first melting point and a second metal layer which has a second melting point lower than the first melting point.

The bumps formed over the first surface of the semiconductor chip may be disposed to cover exposed portions of the bonding pads, which are not covered by the dielectric members, and one half portions of the dielectric members.

The bumps formed over the second surface of the semiconductor chip may be disposed to have an end which is connected with a respective through electrode and an other end which covers one half of a respective dielectric member.

In another embodiment of the present invention, a stacked semiconductor package includes: a first semiconductor package including a semiconductor chip having a first surface and a second surface and formed with a plurality of bonding pads over the first surface, dielectric members formed to expose portions of the respective bonding pads and having a trapezoidal sectional shape, and bumps formed to cover the exposed portions of the respective bonding pads and portions of the dielectric members and having a step-like sectional shape; and a second semiconductor package having the same structure as the first semiconductor package, wherein the first semiconductor package and second semiconductor package are stacked such that the bumps thereof face each other and are connected with each other.

Each bump may include: a first flat portion formed over the exposed portion of the bonding pad; an inclined portion obliquely extending from an end of the first flat portion and formed over a side surface of the dielectric member; and a second flat portion extending from an end of the inclined portion to a middle of an upper surface of the dielectric member.

The bumps may include: a seed metal layer covering the exposed portions of the bonding pads and portions of the dielectric members; and metal plating layers formed over the seed metal layer.

The metal plating layers may include a first metal layer which has a first melting point and a second metal layer which has a second melting point lower than the first melting point.

In another embodiment of the present invention, a stacked semiconductor package includes: a first semiconductor package including a semiconductor chip having a first surface and a second surface and formed with a plurality of bonding pads over the first surface and through electrodes which pass through the first surface and the second surface and are connected with respective bonding pads, dielectric members formed over the first surface the second surface in such a way as to expose portions of the respective bonding pads and not to cover the through electrodes and having a trapezoidal sectional shape, and bumps formed to cover exposed portions of the first surface and the second surface of the semiconductor chip and portions of the respective dielectric members and having a step-like sectional shape; and a second semiconductor package having the same structure as the first semiconductor package, wherein the first semiconductor package and the second semiconductor package are stacked such that the second surface of the second semiconductor package faces the first surface of the first semiconductor package.

Each bump may include: a first flat portion formed over the exposed portion of the bonding pad; an inclined portion obliquely extending from an end of the first flat portion and formed over a side surface of the dielectric member; and a second flat portion extending from an end of the inclined portion to a middle of an upper surface of the dielectric member.

The bumps may include: a seed metal layer covering the exposed portions of the bonding pads and portions of the dielectric members; and metal plating layers formed over the seed metal layer.

The metal plating layers may include a first metal layer which has a first melting point and a second metal layer which has a second melting point lower than the first melting point.

The bumps formed over the first surface of the semiconductor chip may be disposed to cover exposed portions of the bonding pads, which are not covered by the dielectric members, and half of a respective dielectric member.

The bumps formed over the second surface of the semiconductor chip may be disposed to have one end which is connected with a respective through electrode and an other end which covers one half of a respective dielectric member.

### BRIEF DESCRIPTION OF THE DRAWINGS

FIG. 1 is a cross-sectional view illustrating a semiconductor package in accordance with an embodiment of the present invention;

FIGS. 2A to 2G are cross-sectional views sequentially illustrating processes of a method for manufacturing the semiconductor package shown in FIG. 1;

FIG. 3 is a cross-sectional view illustrating a stack structure of a stacked semiconductor package in accordance with another embodiment of the present invention;

FIG. 4 is a cross-sectional view illustrating a semiconductor package in accordance with another embodiment of the present invention;

FIGS. 5 and 6 are cross-sectional views illustrating stack structures of stacked semiconductor packages in accordance with other embodiments of the present invention;

FIG. 7 is a system block diagram of an electronic appliance to which the semiconductor package in accordance with the embodiments of the present invention is applied; and

FIG. 8 is a block diagram illustrating an example of an electronic appliance including the semiconductor package in accordance with the embodiments of the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

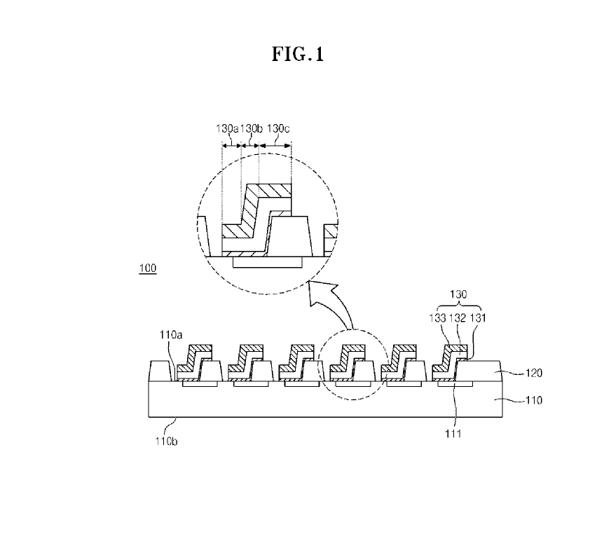

FIG. 1 is a cross-sectional view illustrating a semiconductor package in accordance with an embodiment of the present invention.

Referring to FIG. 1, a semiconductor package 100 in accordance with an embodiment of the present invention includes a semiconductor chip 110, dielectric members 120, and bumps 130.

The semiconductor chip 110 has a first surface 110a and a second surface 110b which faces away from the first surface 110a. At least one of the first surface 110a and the second surface 110b serves as an active surface, and the active surface includes a circuit unit (not shown) and bonding pads 111. In the present embodiment, the first surface 110a is applied as an active surface.

The circuit unit may include, for example, a data storage section for storing data and/or a data processing section for processing data.

A plurality of bonding pads 111 may be disposed at regular intervals (spaces) on the first surface 110a of the semiconductor chip 110.

The dielectric members 120 are formed to selectively cover portions of the bonding pads 111, and have a trapezoidal sectional shape, where each of the dielectric members 120 may selectively cover a portion of a respective bonding pad of the bonding pads 111. Therefore, both side surfaces of the dielectric members 120 are formed to be inclined by a predetermined angle. The dielectric members 120 may function to absorb external shocks applied to the semiconductor package 100.

The bumps 130 function to electrically and mechanically connect a semiconductor chip with a semiconductor chip or a semiconductor chip with a substrate and serve as transmission paths of electrical signals and mechanical junctions.

The bumps 130 are formed to cover exposed portions of respective bonding pad(s) 111, (where the exposed portions of the bonding pads 111 are portions of the bonding pads 111 that are not covered by the dielectric members 120), and substantially cover one half portions of the dielectric members 120. In this regard, the bumps 130 are formed on one side surface of respective dielectric members 120. (In other words, a bump from among the bumps 130 may cover one side surface of a dielectric member from the dielectric members 120.) Thus, the bumps 130 are also inclined at the predetermined angle. As a consequence, the bumps 130 formed to be inclined in this way may be maximally separated from other adjacent bumps within a limited space, thus interference between bumps 130 may be minimized, whereby it is possible to realize bumps with a fine pitch.

Each bump 130 includes a first flat portion 130a which is formed on/over the exposed portion of the bonding pad 111 and may extend beyond the exposed portion of the bonding 111 to cover a portion of the semiconductor chip 110, an inclined portion 130b which obliquely extends from an end of the first flat portion 130a and is formed on the side surface of the dielectric member 120, and a second flat portion 130c which extends from an end of the inclined portion 130b to the middle of the upper surface of the dielectric member 120. Each bump 130 has a step-like sectional shape.

The bump 130 may include, for example, a seed metal layer 131 and metal plating layers 132 and 133.

The seed metal layer 131 is formed on the bonding pad 111 of the semiconductor chip 110. The seed metal layer 131 is formed to extend from the exposed end of the bonding pad 111, which is not covered by the dielectric member 120, to cover a side of the dielectric member 120 and substantially the middle of the upper surface of the dielectric member 120.

The metal plating layers 132 and 133 may be formed on the seed metal layer 131 to have the same length as the seed metal layer 131, and may include a first metal layer 132 which has a first melting point and a second metal layer 133 which has a second melting point lower than the first melting point. For example, the first metal layer 132 may be formed of copper, and the second metal layer 133 may be formed of a solder.

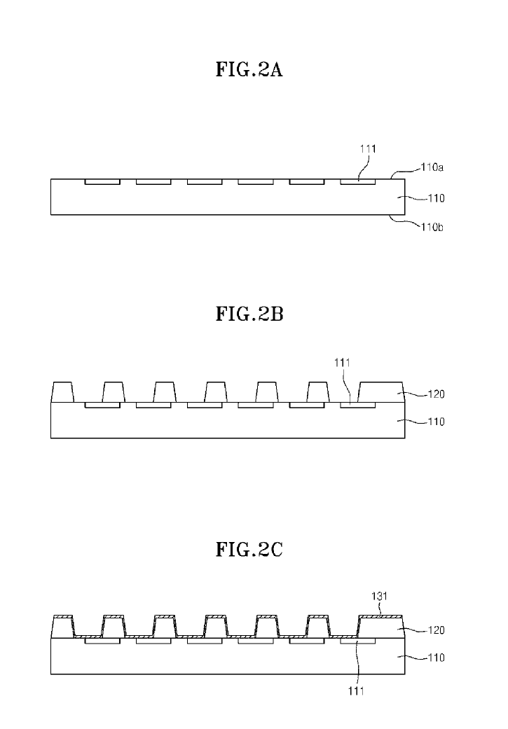

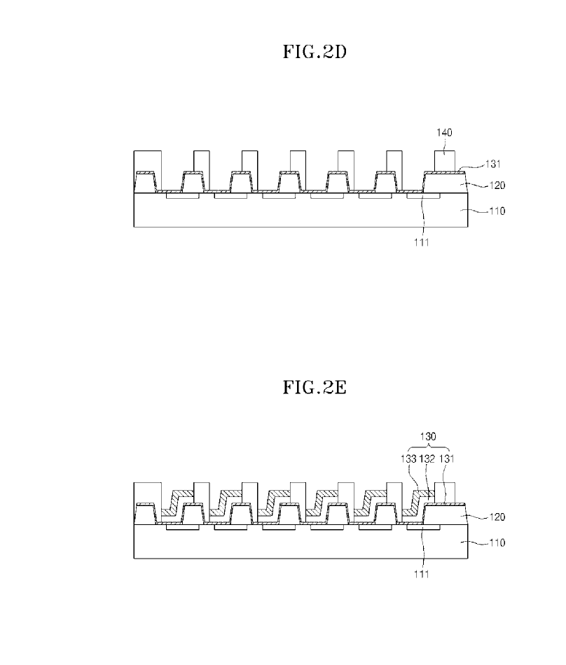

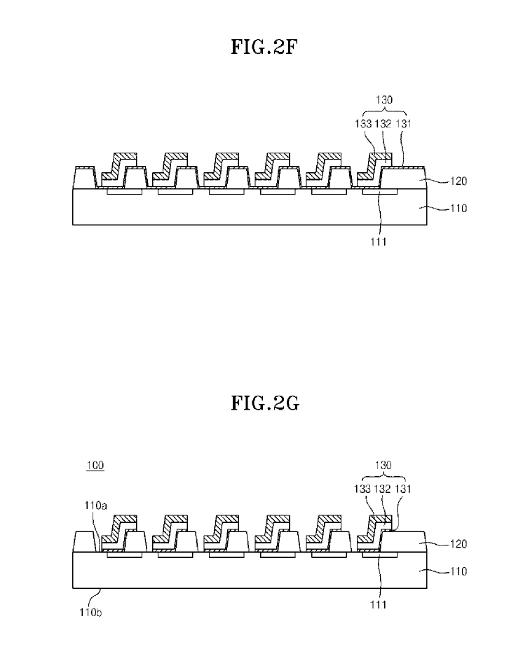

FIGS. 2A to 2G are cross-sectional views sequentially illustrating processes of a method for manufacturing the semiconductor package shown in FIG. 1.

Referring to FIG. 2A, a plurality of bonding pads 111 are formed on a first surface 110a of a semiconductor chip 110 which is manufactured through predetermined unit process.

Referring to FIG. 2B, after a dielectric substance is applied or deposited on the semiconductor chip 110, portions of the dielectric substance are removed in such a way as to expose portions of the bonding pads 111, by which dielectric members 120 with a predetermined height are formed. Further, after removing portions of the dielectric substance, a portion of the dielectric members 120 may each cover a portion of a respective bonding pad from among the bonding pads 111. The dielectric members 120 are patterned to have a trapezoidal sectional shape of which both side surfaces are inclined.

Referring to FIGS. 2C and 2D, a seed metal layer 131 for performing an electroplating process is deposited on the semiconductor chip 110 which is formed with the dielectric members 120. Thereafter, a photoresist 140 is formed on the seed metal layer 131. By partially removing the photoresist 140 using a mask pattern (not shown), portions of the seed metal layer 131 are exposed, where the exposed portions of the seed metal layer 131 are substantially those portions that are placed on portions of the bonding pads 111 and the dielectric members 120. The photoresist 140 functions to maximize an electroplating area over which an electroplating process is to be performed subsequently, so that a desired structure may be obtained.

Referring to FIG. 2E, metal plating layers 132 and 133 are formed on the seed metal layer 131 by performing a plating process on the semiconductor chip 110, by which bumps 130 are completely formed. The height of the bumps 130 is determined in consideration of conditions of hot-pressing for bonding another semiconductor chip (or a printed circuit board) in a subsequent bonding process.

Referring to FIG. 2F, the photoresist 140 remaining on the semiconductor chip 110 is completely removed through a stripping process. After the photoresist 140 is removed, portions of the seed metal layer 131 that are uncovered and/or exposed remain on the dielectric members 120 and the semiconductor chip 110.

Referring to FIG. 2G, by etching exposed portions of the seed metal layer 131 after removing the photoresist 140, the respective bumps 130 are formed to have inclined portions. Accordingly, since the distance between two adjacent bumps may be maximized within a limited space, it is possible to manufacture a semiconductor package with a fine pitch.

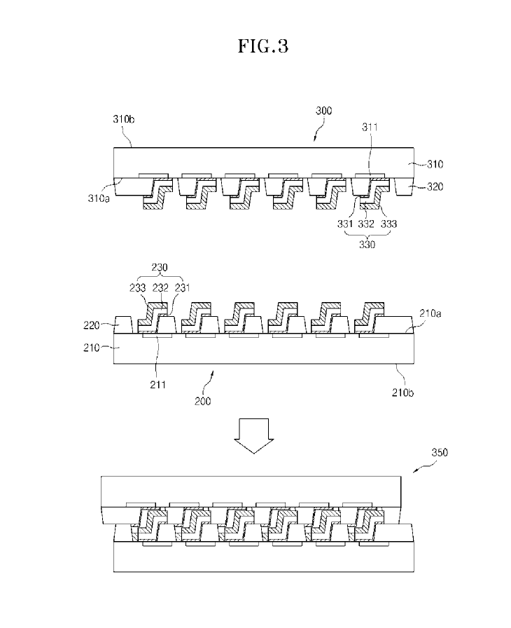

FIG. 3 is a cross-sectional view illustrating a stack structure of a stacked semiconductor package in accordance with another embodiment of the present invention.

Referring to FIG. 3, a stacked semiconductor package in accordance with another embodiment of the present invention includes a first semiconductor package 200 and a second semiconductor package 300. The first semiconductor package 200 and the second semiconductor package 300 are stacked such that their respective active surfaces face each other.

The first semiconductor package 200 and the second semiconductor package 300 include semiconductor chips 210 and 310, dielectric members 220 and 320, and bumps 230 and 330.

The semiconductor chips 210 and 310 have first surfaces 210a and 310a and second surfaces 210b and 310b which face away from the first surfaces 210a and 310a. Active surfaces 210a and 310a of the semiconductor chips 210 and 310 include circuit units (not shown) and bonding pads 211 and 311. The circuit units may include, for example, data storage sections for storing data and/or data processing sections for processing data. A plurality of bonding pads 211 and 311 may be disposed at regular intervals (spaces), for example, on upper surfaces of the semiconductor chips 210 and 310.

The dielectric members 220 and 320 are projectedly formed to selectively cover portions of the bonding pads 211 and 311, and have a trapezoidal sectional shape. Therefore, side surfaces of the dielectric members 220 and 320 are formed to be inclined by a predetermined angle.

The bumps 230 and 330 are formed to cover exposed portions of the bonding pads 211 and 311, where the exposed portions of the bonding pads 211 and 311 are those portions of the bonding pads 211 and 311 that are not covered by the dielectric members 220 and 320. Further, the bumps 230 and 330 are formed to cover substantially one half portions of the dielectric members 220 and 320. In this regard, since the bumps 230 and 330 are formed on one side surface of the dielectric members 220 and 320, the bumps 230 and 330 are also inclined by the same predetermined angle as the dielectric member 120. As a consequence, since the bumps 230 and 330 are formed to be inclined in this way, the each bump may minimally interfere with other adjacent bumps, it is possible to realize bumps with a fine pitch.

The bumps 230 and 330 may include, for example, seed metal layers 231 and 331 and metal plating layers 232 and 233, and 332 and 333.

The seed metal layers 231 and 331 are formed on the bonding pads 211 and 311 of the semiconductor chips 210 and 310. The seed metal layers 231 and 331 are formed to extend from exposed ends of the bonding pads 211 and 311 which are not covered by the dielectric members 220 and 320, to substantially the middles of the upper surfaces of the dielectric members 220 and 320 where the dielectric members project outward from a surface of the semiconductor chips 210 and 310. The metal plating layers 232 and 233, and 332 and 333 may be formed on the seed metal layers 231 and 331 to have the same length as the seed metal layers 231 and 331, and may include first metal layers 232 and 332 which have a first melting point and second metal layers 233 and 333 which have a second melting point lower than the first melting point. For example, the first metal layers 232 and 332 may be formed of copper, and the second metal layers 233 and 333 may be formed of a solder.

In the stacked semiconductor package in accordance with an embodiment, the first semiconductor package 200 and the second semiconductor package 300 are stacked such that the first surface 210a of the first semiconductor package 200 and the first surface 310a of the second semiconductor package 300 face each other. That is to say, by performing hot-pressing after the bumps 230 and 330 of the respective semiconductor packages 200 and 300 are connected with each other, a stack structure 350 comprising two unit semiconductor packages may be formed.

Since the respective bumps 230 and 330 are formed to be inclined, the distance between two adjacent bumps may be sufficiently secured, and since the respective bumps 230 and 330 are isolated from one another by the dielectric members 220 and 320 positioned therebetween, it is possible to prevent the occurrence of short-circuiting.

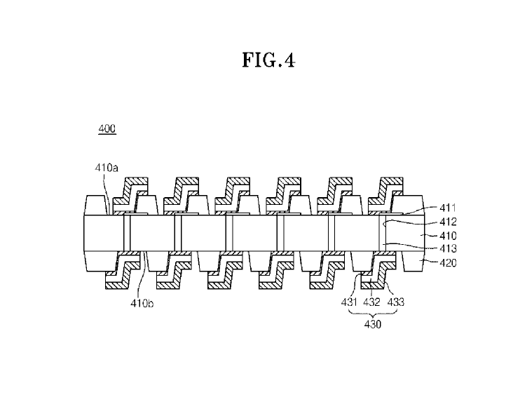

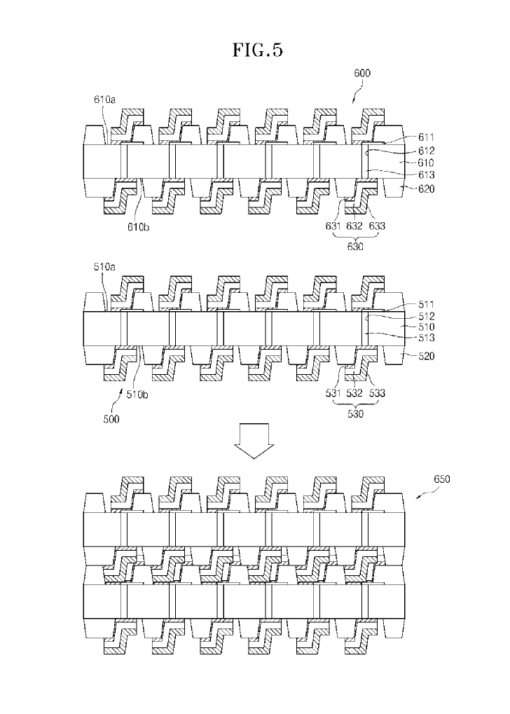

FIG. 4 is a cross-sectional view illustrating a semiconductor package in accordance with another embodiment of the present invention.

Referring to FIG. 4, a semiconductor package 400 in accordance with another embodiment of the present invention includes a semiconductor chip 410 which has a first surface 410a which is formed with a plurality of bonding pads 411 spaced at regular intervals, and a second surface 410b. In some embodiments, it may be that the second surface 410b does not include bonding pads 411.

The semiconductor chip 410 includes via holes 412 which pass through the first surface 410a and the second surface 410b to be connected with the bonding pads 411, and through electrodes 413 are formed in the respective via holes 412 and connect with respective bonding pads 411. The semiconductor chip 410 further includes dielectric members 420 and bumps 430 which are formed on the first surface 410a and the second surface 410b at regular intervals.

The dielectric members 420 are projectedly formed on the first surface 410a and the second surface 410b of the semiconductor chip 410, such that the dielectric members 420 are not in contact with the through electrodes 413, and have a trapezoidal sectional shape. Accordingly, both side surfaces of the dielectric members 420 are formed to be inclined by a predetermined angle. The dielectric members 420 formed on the first surface 410a are disposed to selectively cover portions of the bonding pads 411.

The bumps 430 are formed to extend from exposed portions of the first surface 410a and the second surface 410b of the semiconductor chip 410 to portions of respective dielectric members 420. The bumps 430 formed on the first surface 410a are formed to cover remaining portions of the bonding pads 411 which are not covered by the dielectric members 420, and the bumps 430 may cover one half of the dielectric members 420. The bumps 430 formed on the second surface 410b are formed to have an end which is connected with a respective through electrode from among the through electrodes 413 and an other end which covers a one half of portion of a respective dielectric member from among the dielectric members 420. Accordingly, the bumps 430 formed on the first surface 410a and the bumps 430 formed on the second surface 410b may be electrically connected with each other by the through electrodes 413. Because the respective bumps 430 are formed on the side surfaces of the dielectric members 420 with a trapezoidal sectional shape, the bumps 430 are also inclined by the same predetermined angle as the dielectric member 420 side on which the bumps 430 are formed. As a consequence, since the bumps 430 are formed to be inclined in this way, each bump may minimally interfere with other adjacent bumps, thus it is possible to realize bumps with a fine pitch.

The bumps 430 may include, for example, a seed metal layer 431 which is formed on the bonding pads 411 of the first surface 410a and is formed on the second surface 410b, and metal plating layers 432 and 433 which are formed on the seed metal layer 431.

On the first surface 410a, the seed metal layer 431 is formed to extend from portions of the bonding pads 411, which are not covered by the dielectric members 420 and are exposed, to portions of the dielectric members 420. On the second surface 410b, the seed metal layer 431 may be formed to extend from the exposed through electrodes 413 to portions of the dielectric members 420. The metal plating layers 432 and 433 may be formed on the seed metal layer 431 to have the same length as the seed metal layer 431, and may include a first metal layer 432 which has a first melting point and a second metal layer 433 which has a second melting point lower than the first melting point. For example, the first metal layer 432 may be formed of copper, and the second metal layer 433 may be formed of a solder.

FIG. 5 is a cross-sectional view illustrating a stack structure of a stacked semiconductor package in accordance with another embodiment of the present invention.

Referring to FIG. 5, a stacked semiconductor package in accordance with another embodiment of the present invention includes a first semiconductor package 500 and a second semiconductor package 600. The first semiconductor package 500 and the second semiconductor package 600 are stacked such that a first surface 510a of the first semiconductor package 500 and a second surface 610b of the second semiconductor package 600 face each other.

The first semiconductor package 500 and the second semiconductor package 600 include semiconductor chips 510 and 610, dielectric members 520 and 620, and bumps 530 and 630.

The semiconductor chips 510 and 610 have first surfaces 510a and 610a and second faces 510b and 610b, and are formed with a plurality of bonding pads 511 and 611 at regular intervals. The semiconductor chips 510 and 610 include via holes 512 and 612 which pass through the first surfaces 510a and 610a and the second surfaces 510b and 610b to be connected with the bonding pads 511 and 611, and through electrodes 513 and 613 are formed in the respective via holes 512 and 612.

The dielectric members 520 and 620 are projectedly formed on the first surface 510a and the second surface 610b of the semiconductor chips 510 and 610 such that the dielectric members 520 and 620 are not in direct contact with the through electrodes 513 and 613, and the dielectric members 520 and 620 have a trapezoidal sectional shape. Accordingly, both side surfaces of the dielectric members 520 and 620 are formed to be inclined by a predetermined angle. The dielectric members 520 and 620 formed on the first surfaces 510a and 610a are disposed to selectively cover portions of the bonding pads 511 and 611.

The bumps 530 and 630 formed on the first surfaces 510a and 610a are formed to cover the remaining portions of the bonding pads 511 and 611, which are not covered by the dielectric members 520 and 620, and the bumps 530 and 630 may each cover one half of a respective dielectric member from among the dielectric members 520 and 620. The bumps 530 and 630 formed on the second surfaces 510b and 610b are formed to have one end which is connected with the through electrodes 513 and 613 and other ends which cover one half portions of the dielectric members 520 and 620. Accordingly, the bumps 530 and 630 formed on the first surfaces 510a and 610a and the bumps 530 and 630 formed on the second surfaces 510b and 610b may be electrically connected with each other by the through electrodes 513 and 613.

Because the respective bumps 530 and 630 are formed on the side surfaces of the dielectric members 520 and 620 with a trapezoidal sectional shape, the bumps 530 and 630 are also inclined by the same predetermined angle as the side of the dielectric members 520 and 620 on which the bumps 530 and 630 are formed. As a consequence, since the bumps 530 and 630 are formed to be inclined in this way, each bump may be minimally interfere with other adjacent bumps, thus it is possible to realize bumps with a fine pitch.

The bumps 530 and 630 may include, for example, seed metal layers 531 and 631 which are formed on the bonding pads 511 and 611 on the first surfaces 510a and 610a and the seed metal layers 531 and 631 may be formed on the second surfaces 510b and 610b. The bumps 530 and 630 may also include metal plating layers 532 and 533 and 632 and 633 which are formed on the seed metal layers 531 and 631.

The seed metal layers 531 and 631 are formed to extend from exposed portions of the bonding pads 511 and 611, which are not covered by the dielectric members 520 and 620, to portions of the dielectric members 520 and 620. The metal plating layers 532 and 533 and 632 and 633 may be formed on the seed metal layers 531 and 631 to have the same length as the seed metal layers 531 and 631, and may include first metal layers 532 and 632 which have a first melting point and second metal layers 533 and 633 which have a second melting point lower than the first melting point. For example, the first metal layers 532 and 632 may be formed of copper, and the second metal layers 533 and 633 may be formed of a solder.

In the stacked semiconductor package in accordance with the present embodiment, by performing hot-pressing after the first semiconductor package 500 and the second semiconductor package 600 are stacked such that the bumps 530 formed on the first surface 510a of the first semiconductor package 500 and the bumps 630 formed on the second surface 610a of the second semiconductor package 600 are connected with each other, a stack structure comprising two unit semiconductor packages 650 may be formed.

Since the respective bumps 530 and 630 are formed to be inclined, the distance between two adjacent bumps may be sufficiently secured, and since the respective bumps 530 and 630 are isolated from one another by the dielectric members 520 and 620 positioned therebetween, it is possible to prevent the occurrence of short-circuiting.

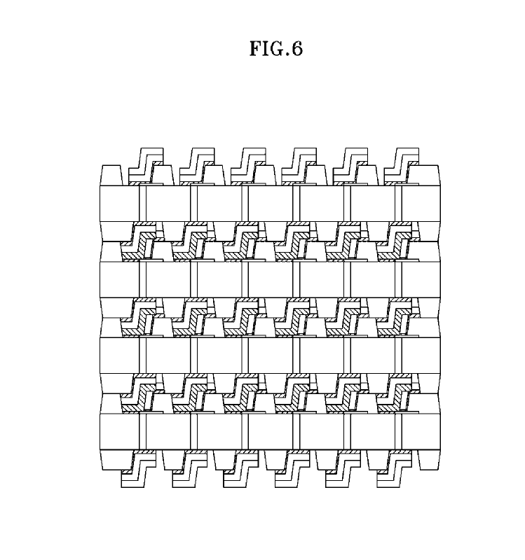

By extendedly applying such a scheme, as shown in FIG. 6, in a stacked semiconductor package in accordance with another embodiment of the present invention, at least three unit semiconductor packages may be easily stacked.

The above-described semiconductor package technologies may be applied to various kinds of semiconductor devices and package modules having the same.

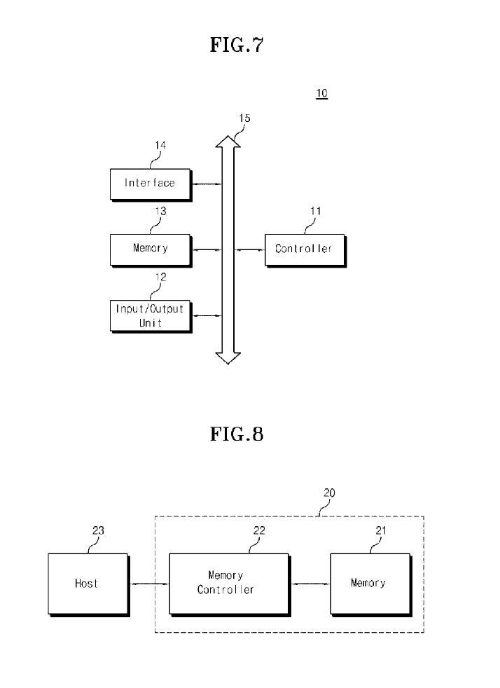

Referring to FIG. 7, the semiconductor package in accordance with another embodiment of the present invention may be applied to an electronic system 10. An electronic system 10 may include a controller 11, an input/output unit 12, a memory 13, and an interface 14. The controller 11, the input/output unit 12 and the memory 13 may be coupled with one another through a bus 15 providing a path through which data move.

For example, the controller 11 may include at least any one of at least one microprocessor, at least one digital signal processor, at least one microcontroller, and logic devices capable of performing the same functions as these components. The controller 11 and the memory 13 may include at least any one of the semiconductor packages according to the embodiments of the present invention. The input/output unit 12 may include at least one selected from among a keypad, a keyboard, a display device, and so forth. The memory 13 is a device for storing data. The memory 13 may store data and/or commands to be executed by the controller 11, and the like.

The memory 13 may include a volatile memory device such as a DRAM and/or a nonvolatile memory device such as a flash memory. For example, a flash memory may be mounted to an information processing system such as a mobile terminal or a desk top computer. The flash memory may be constituted by a semiconductor disc device (SSD). In this case, the electronic system 10 may stably store a large amount of data in a flash memory system.

The electronic system 10 may further include an interface configured to transmit and receive data to and from a communication network. The interface 14 may be a wired or wireless type. For example, the interface 14 may include an antenna or a wired or wireless transceiver. Further, the electronic system 10 may be additionally provided with an application chipset, a camera image processor (CIS), an input/output unit, etc.

The electronic system 10 may be realized as a mobile system, a personal computer, an industrial computer or a logic system performing various functions. For example, the mobile system may be any one of a personal digital assistant (PDA), a portable computer, a web tablet, a mobile phone, a wireless phone, a laptop computer, a memory card, a digital music system and an information transmission/reception system. When the electronic system 10 is equipment capable of performing wireless communication, the electronic system 10 may be used in a communication system such as of CDMA (code division multiple access), GSM (global system for mobile communication), NADC (north American digital cellular), E-TDMA (enhanced-time division multiple access), WCDAM (wideband code division multiple access) and CDMA2000.

Referring to FIG. 8, the semiconductor package in accordance with embodiments of the present invention may be provided in the form of a memory card 20. For example, the memory card 20 may include a memory 21 such as a nonvolatile memory device and a memory controller 22. The memory 21 and the memory controller 22 may store data or read stored data. The memory 21 may include at least any one among nonvolatile memory devices to which the packaging technology of embodiments of the present invention is applied. The memory controller 22 may control the memory 21 such that stored data is read out or data is stored in response to a read/write request from a host 23.

Although specific embodiments of the present invention have been described for illustrative purposes, those skilled in the art will appreciate that various modifications, additions and substitutions are possible, without departing from the scope and the spirit of the invention.

What is claimed is:

1. A semiconductor package comprising:
a semiconductor chip having a plurality of bonding pads;
dielectric members formed over the semiconductor chip in such a way as to expose portions of respective bonding pads and having a trapezoidal sectional shape; and
bumps formed to cover the exposed portions of the respective bonding pads and portions of the dielectric members and having a step-like sectional shape.

2. The semiconductor package according to claim 1, wherein each bump comprises:
a first flat portion formed over the exposed portion of the bonding pad;
an inclined portion obliquely extending from an end of the first flat portion and formed over a side surface of the dielectric member; and
a second flat portion extending from an end of the inclined portion to a middle of an upper surface of the dielectric member.

3. The semiconductor package according to claim 1, wherein the bumps comprise:
a seed metal layer covering the exposed portions of the bonding pads and portions of the dielectric members; and
metal plating layers formed over the seed metal layer.

4. The semiconductor package according to claim 3, wherein the metal plating layers include a first metal layer which has a first melting point and a second metal layer which has a second melting point lower than the first melting point.

5. A semiconductor package comprising:
a semiconductor chip having a first surface on which a plurality of bonding pads are formed and a second surface which faces away form the first surface, and formed with through electrodes which pass through the first surface and the second surface and are connected with respective bonding pads;
dielectric members formed over the first surface in such a way as to expose portions of the respective bonding pads and, formed over the first and second surface such that the through electrodes are not covered and where the dielectric members have a trapezoidal sectional shape; and
bumps formed over exposed portions of the first surface and the second surface of the semiconductor chip and portions of the dielectric members, and having a step-like sectional shape.

6. The semiconductor package according to claim 5, wherein each bump comprises:
a first flat portion formed over the exposed portion of the bonding pad;
an inclined portion obliquely extending from an end of the first flat portion and formed over a side surface of the dielectric member; and
a second flat portion extending from an end of the inclined portion to a middle of an upper surface of the dielectric member.

7. The semiconductor package according to claim 5, wherein the bumps comprise:
a seed metal layer covering the exposed portions of the bonding pads and portions of the dielectric members; and
metal plating layers formed over the seed metal layer.

8. The semiconductor package according to claim 7, wherein the metal plating layers include a first metal layer which has a first melting point and a second metal layer which has a second melting point lower than the first melting point.

9. The semiconductor package according to claim 5, wherein the bumps formed over the first surface of the semiconductor chip are disposed to cover exposed portions of the bonding pads, which are not covered by the dielectric members, and one half portions of the dielectric members.

10. The semiconductor package according to claim 5, wherein the bumps formed over the second surface of the semiconductor chip are disposed to have an end which is connected with a respective through electrode and an other end which covers one half of a respective dielectric member.

11. A stacked semiconductor package comprising:
a first semiconductor package including a semiconductor chip having a first surface and a second surface and formed with a plurality of bonding pads over the first surface, dielectric members formed to expose portions of the respective bonding pads and having a trapezoidal sectional shape, and bumps formed to cover the exposed portions of the respective bonding pads and portions of the dielectric members and having a step-like sectional shape; and
a second semiconductor package having the same structure as the first semiconductor package,
wherein the first semiconductor package and second semiconductor package are stacked such that the bumps thereof face each other and are connected with each other.

12. The stacked semiconductor package according to claim 11, wherein each bump comprises:
a first flat portion formed over the exposed portion of the bonding pad;
an inclined portion obliquely extending from an end of the first flat portion and formed over a side surface of the dielectric member; and
a second flat portion extending from an end of the inclined portion to a middle of an upper surface of the dielectric member.

13. The stacked semiconductor package according to claim 11, wherein the bumps comprise:
a seed metal layer covering the exposed portions of the bonding pads and portions of the dielectric members; and
metal plating layers formed over the seed metal layer.

14. The stacked semiconductor package according to claim 13, wherein the metal plating layers include a first metal layer which has a first melting point and a second metal layer which has a second melting point lower than the first melting point.

15. A stacked semiconductor package comprising:
a first semiconductor package including a semiconductor chip having a first surface and a second surface and formed with a plurality of bonding pads over the first surface and through electrodes which pass through the first surface and the second surface and are connected with respective bonding pads, dielectric members formed over the first surface the second surface in such a way as to expose portions of the respective bonding pads and not to cover the through electrodes and having a trapezoidal sectional shape, and bumps formed to cover exposed portions of the first surface and the second surface of the semiconductor chip and portions of the respective dielectric members and having a step-like sectional shape; and
a second semiconductor package having the same structure as the first semiconductor package,
wherein the first semiconductor package and the second semiconductor package are stacked such that the second surface of the second semiconductor package faces the first surface of the first semiconductor package.

16. The stacked semiconductor package according to claim 15, wherein each bump comprises:
a first flat portion formed over the exposed portion of the bonding pad;
an inclined portion obliquely extending from an end of the first flat portion and formed over a side surface of the dielectric member; and
a second flat portion extending from an end of the inclined portion to a middle of an upper surface of the dielectric member.

17. The stacked semiconductor package according to claim 15, wherein the bumps comprise:
a seed metal layer covering the exposed portions of the bonding pads and portions of the dielectric members; and
metal plating layers formed over the seed metal layer.

18. The stacked semiconductor package according to claim 17, wherein the metal plating layers include a first metal layer which has a first melting point and a second metal layer which has a second melting point lower than the first melting point.

19. The stacked semiconductor package according to claim 15, wherein the bumps formed over the first surface of the semiconductor chip are disposed to cover exposed portions of the bonding pads, which are not covered by the dielectric members, and half of a respective dielectric member.

20. The stacked semiconductor package according to claim 15, wherein the bumps formed over the second surface of the semiconductor chip are disposed to have one end which is connected with a respective through electrode and an other end which covers one half of a respective dielectric member.
